(19) United States
(12) Patent Application Publication
(10) Pub. No.: US 2009/0243051 A1
(43) Pub. Date: Oct. 1, 2009

(54) INTEGRATED CONDUCTIVE SHIELD FOR MICROELECTRONIC DEVICE ASSEMBLIES AND ASSOCIATED METHODS

(75) Inventors: Kiran Kumar Vanam, Boise, ID (US); Alan G. Wood, Boise, ID (US); James M. Derderian, Boise, ID (US); Derek J. Gochnour, Boise, ID (US); Owen R. Fay, Meridian, ID (US); Luke G. England, Portland, ME (US)

Correspondence Address: PERKINS COIE LLP;PATENT-SEA, PO BOX 1247, SEATTLE, WA, 98111-1247, US

(73) Assignee: MICRON TECHNOLOGY, INC., Boise, ID (US)

(21) Appl. No.: 12/058,244

(22) Filed: Mar. 28, 2008

(51) Int. Cl. H01L 23/552; H01L 21/56

(52) U.S. Cl. 257/659; 438/127; 257/E21.506; 257/E23.114

(57) ABSTRACT

Microelectronic device assemblies having integrated conductive shields are disclosed herein. The microelectronic device assemblies include a semiconductor substrate having a bond site and a solder ball electrically connected to the bond site, a dielectric sidewall at least partially encapsulating the semiconductor substrate, and a conductive shield in direct contact with the sidewall and in electrical communication with the solder ball and the bond site.

### TECHNICAL FIELD

The present disclosure is directed to conductive shield structures for suppressing electromagnetic interference (EMI) in microelectronic device assemblies and associated methods for making such structures.

### BACKGROUND

Semiconductor imagers typically include an array of photodiodes that can detect visible light with spatial resolution. However, EMI can impair the performance of imagers. For example, photodiodes typically cannot distinguish different types of radiation coming from different sources, and thus can generate dark current from background radiation even without being exposed to visible light. EMI can also introduce electrical noise that affects processing of electrical circuits associated with the imagers. In addition, EMI emitted from imagers and/or other components of a device (e.g., communication circuitry on a cellular phone) may interfere with one another to degrade device performance. Furthermore, increasing levels of component integration, radio frequency interference on a motherboard of a system, and FCC compliance may require imagers to be shielded from external electromagnetic emissions and/or may require shielding the imagers from emitting into an environment. As a result, EMI must be suppressed or eliminated for proper functioning of the device.

FIG. 1 illustrates an imager assembly 100 having an EMI suppressing structure in accordance with the prior art. As shown in FIG. 1, the imager assembly 100 includes an imager die 102, an objective lens 120 attached to a first surface 104a of the imager die 102, a plurality of solder balls 105 attached to a second surface 104b of the imager die 102, and an encapsulant 122 encapsulating the objective lens 120 and the imager die 102. The imager die 102 typically includes a sensor array 106 (e.g., a CMOS or CCD sensor array) at the first surface 104a and a plurality of vias 108 extending between the first and second surfaces 104a-b to electrically connect the sensor array 106 and/or other internal circuitry (not shown) of the imager die 102 to the solder balls 105. As shown in FIG. 1, the EMI suppressing structure 130 includes a metal housing that has a first opening 126a for receiving a portion of the objective lens 120 and a second opening 126b for receiving the encapsulated imager die 102 and the objective lens 120.

One drawback of the foregoing imager assembly 100 is that the EMI suppressing structure 130 is large and increases the footprint of the imager assembly 100. As shown in FIG. 1, the metal housing is larger than the imager die 102 to receive and enclose the encapsulated imager die 102. Such a large footprint, however, is undesirable because cell phones, cameras, and other portable devices are continually requiring smaller components. Accordingly, there is a need for an improved EMI suppressing structure that can reduce the footprint of the imager assembly.

### BRIEF DESCRIPTION OF THE DRAWINGS

FIG. 1 is a partially schematic cross-sectional view of an imager assembly with an EMI suppressing structure in accordance with the prior art.

FIG. 2 is a partially schematic cross-sectional view of a microelectronic device assembly having a conductive shield in accordance with an embodiment of the disclosure.

FIGS. 3-9 illustrate a process for forming the microelectronic device assembly shown in FIG. 2 in accordance with an embodiment of the disclosure.

FIG. 10 is a partially schematic cross-sectional view of a microelectronic device assembly having a conductive shield in accordance with another embodiment of the disclosure.

FIGS. 11-16 illustrate a process for forming the microelectronic device assembly shown in FIG. 2 in accordance with an embodiment of the disclosure.

FIG. 17 is a schematic diagram of a system that includes one or more microfeature dies in accordance with embodiments of the disclosure.

### DETAILED DESCRIPTION

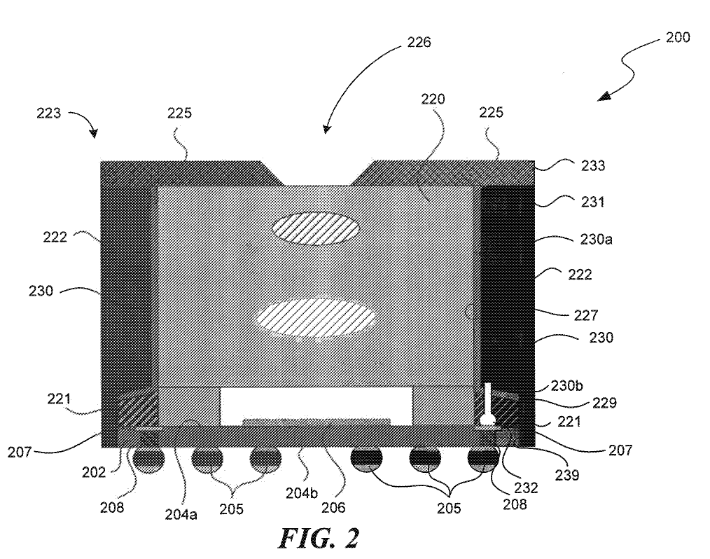

Specific details of several embodiments of the disclosure are described below with reference to microelectronic device assemblies having conductive shields and methods of manufacturing. Typical microelectronic device assemblies include microelectronic circuits or components, thin-film recording heads, data storage elements, microfluidic devices, and other products. Micromachines and micromechanical devices are included within this definition because they are manufactured using much of the same technology that is used in the fabrication of integrated circuits. Substrates can be semiconductor pieces (e.g., doped silicon wafers or gallium arsenide wafers), nonconductive pieces (e.g., various ceramic substrates), or conductive pieces. A person skilled in the relevant art will also understand that the disclosure may have additional embodiments, and that the disclosure may be practiced without several of the details of the embodiments described below with reference to FIGS. 2-17.

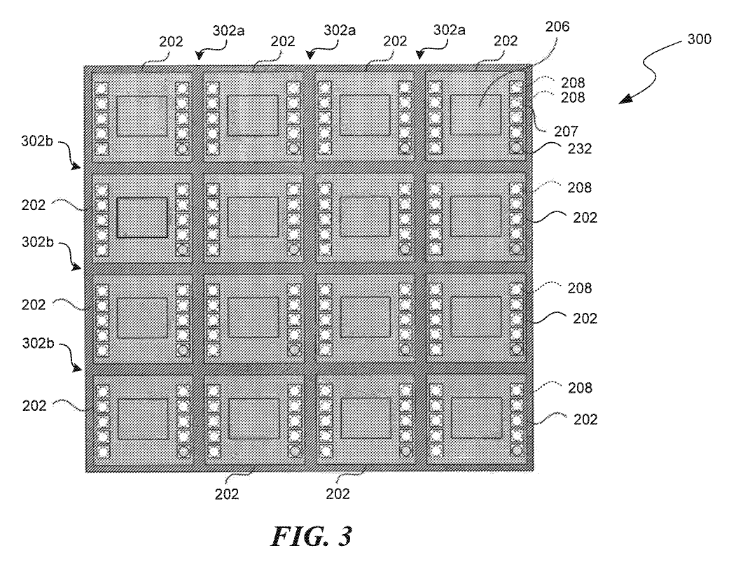

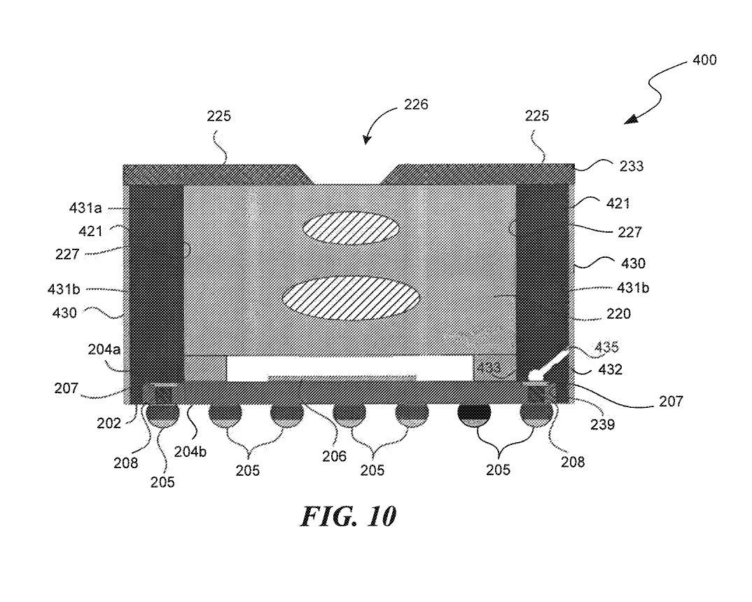

FIG. 2 illustrates a first embodiment of a microelectronic device assembly having a conductive shield, and FIGS. 3-9 show methods of manufacturing the embodiment shown in FIG. 2. FIG. 10 illustrates a second embodiment of the microelectronic device assembly, and FIGS. 11-16 show methods of manufacturing the embodiment shown in FIG. 10. These embodiments and other embodiments described herein can have generally similar components and functions. As a result, common acts and structures are identified by the same reference numbers.

FIG. 2 is a partially schematic cross-sectional view of a microelectronic device assembly having a conductive shield in accordance with an embodiment of the disclosure. In the illustrated embodiment, the microelectronic device assembly is shown as an imager assembly 200. However, in other embodiments, the microelectronic device assembly can also include radio frequency transceivers and/or other suitable microelectronic devices.

As shown in FIG. 2, the imager assembly 200 can include an imager die 202, an objective lens 220 attached to a first surface 204a of the imager die 202, and a plurality of solder balls 205 attached to a second surface 204b of the imager die 202. The first and second surfaces 204a-b are generally opposite to one another. The imager die 202 can include a sensor array 206 (e.g., a CMOS or a CCD sensor array) proximate to the first surface 204a, a plurality of bond sites 207, a plurality of vias 208 between the first and second surfaces 204a-b, and internal signal processing circuits (e.g., column/row-select circuits, analog signal processors, timing and control circuits, A/D converters, and digital signal processors). At least some of the bond sites 207 are in electrical communication with the sensor array 206 and/or the signal processing circuits, and the vias 208 electrically connect the bond sites 207 to the solder balls 205 for external access. The objective lens 220 is configured to present the radiation to the sensor 206, and the objective lens 220 can have many different configurations. For example, the objective lens 220 can be constructed from glass, polymers, a combination of glass and polymers, and/or other suitable transparent material. The objective lens 220 can also be configured as a single layer or a multilayer structure. Optionally, in certain embodiments, the imager assembly 200 can also include a protective lens cover (not shown) proximate to the objective lens 220. In the embodiment shown in FIG. 2, the objective lens 220 has side surfaces 227 extending away from the imager die 202.

The imager assembly 200 can also include a dielectric first sidewall 221 carried by the imager die 202 around a lower portion of the objective lens 220, a conductive shield 230 for suppressing EMI, and a shield interconnect 232 extending between one of the bond sites 207 and the conductive shield 230. The conductive shield 230 can be in direct contact with both the objective lens 220 and the first sidewall 221. Even though the imager assembly 200 is shown as having one shield interconnect 232, in several embodiments, the imager assembly 200 can have any desired number of shield interconnects.

The first sidewall 221 can include an epoxy and/or other suitable encapsulating material disposed onto the bond sites 207 of the imager die 202, the shield interconnect 232, and a portion of the objective lens 220. In the illustrated embodiment, the first sidewall 221 includes a tapered upper surface 229. In other embodiments, the upper surface 229 can be generally parallel to the first surface 204a or can have other suitable configurations.

The conductive shield 230 can include a layer of conductive material having a first portion 230a in direct contact with the side surfaces 227 of the objective lens 220 and a second portion 230b in direct contact with the upper surface 229 of the first sidewall 221. The conductive material can include copper, aluminum, nickel, gold, silver, platinum, and/or other suitable metal or metal alloys. The conductive material can also include carbon, doped polysilicon, and/or other conductive non-metallic material. In one embodiment, the conductive shield 230 can include a layer of copper with a thickness of about 1 micrometer to about 10 micrometers electroplated onto the lens side surfaces 227 and the upper surface 229. In other embodiments, the conductive shield 230 can include a layer of conductive material with any desired thicknesses that is deposited, laminated, or otherwise suitably applied to the lens side surface 227 and the upper surface 229 of the first sidewall 221. Even though the conductive shield 230 is shown to have a generally uniform thickness in FIG. 2, in certain embodiments, portions of the conductive shield 230 may have different thicknesses.

The shield interconnect 232 can include a volume of conductive material (e.g., gold, copper, aluminum, and/or other suitable metal or metal alloy) extending through the first sidewall 221 between a bond site 207 and the conductive shield 230. In the illustrated embodiment, the shield interconnect 232 includes a stud bump extending from the bond site 207, through the first sidewall 221, and beyond the conductive shield 230. In other embodiments, the shield interconnect 232 can be generally flush and/or otherwise in direct contact with the conductive shield 230. In yet other embodiments, the shield interconnect 232 can include other configurations as described in more detail below with reference to FIGS. 10-16.

The imager assembly 200 can also include an outer casing 223 that encapsulates the imager die 202, the objective lens 220, the first sidewall 221, and the conductive shield 230. The outer casing 223 can include a hood 225 and a second sidewall 222 forming at least a partial enclosure. The hood 225 can be in direct contact with the objective lens 220 and can also include an opening 226 for receiving a portion of the objective lens 220. The hood 225 can be constructed from a molded epoxy compound and/or other suitable polymeric material for protecting and insulating the objective lens 220 and with sufficient opaqueness for blocking stray light from entering the objective lens 220. The hood 225 can also function as a carrier for the objective lens 220 during assembly. In one embodiment, the hood 225 can have the same composition as the second sidewall 222. In other embodiments, the hood 225 can have different composition from the second sidewall 222.

The second sidewall 222 can include an epoxy and/or other suitable encapsulating material in direct contact with the conductive shield 230, the first sidewall 221, and the imager die 202. The material of the second sidewall 222 can be the same as or different from that of the sidewall 221. In the illustrated embodiment, the second sidewall 222 has side surfaces 231 generally aligned with corresponding tape side surfaces 233 of the hood 225 and extending beyond an edge 239 of the imager die 202. In other embodiments, the second sidewall 222 can be (a) offset from corresponding tape side surfaces 233, (b) generally aligned with the edge 239 of the imager die 202, and/or (c) configured in other suitable configurations.

In operation, the conductive shield 230 can reduce or eliminate external electromagnetic, electrical, and/or magnetic interference to the imager die 202. For example, when the imager assembly 200 is exposed to an external EMI source (not shown), the external EMI source can induce charges in the conductive shield 230. The shield interconnect 232, the bond site 207 carrying the shield interconnect 232, the via 208 and one of the solder balls 205 corresponding to the bond site 207 provide a conductive path to ground for conducting the induced charges away from the conductive shield 230. The conductive shield 230 and the shield interconnect 232 accordingly shield the imager die 202 from the external EMI source. As a result, the conductive shield 230 can at least reduce dark current and/or other adverse effects induced by the external EMI source.

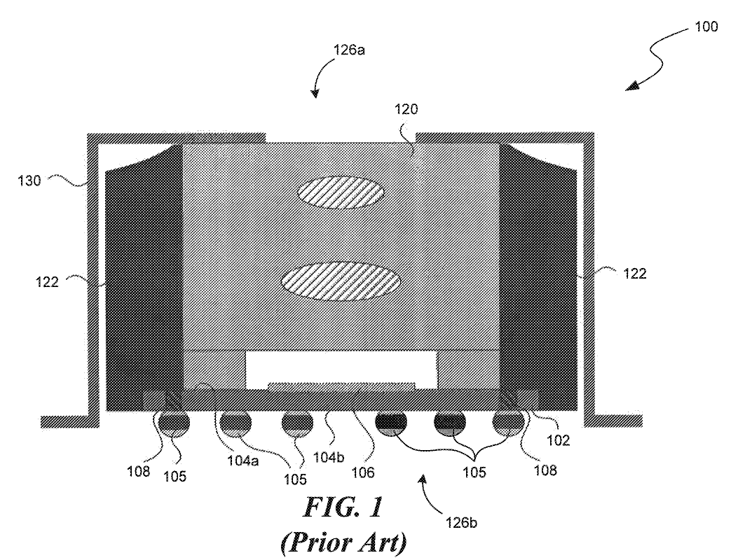

Several embodiments of the conductive shield 230 can have a smaller footprint than that of the prior art because the conductive shield 230 is integrated into the imager assembly 200. The conventional conductive shield 130 shown in FIG. 1 typically has a footprint larger than that of the imager die 102. As a result, the imager assembly 100 requires a large surface area when being mounted onto a substrate (e.g., a printed circuit board). In contrast, several embodiments of the conductive shield 230 shown in FIG. 2 can have a footprint that is proximately the same as or even smaller than the footprint of the imager die 202 to reduce the amount of surface area occupied by the microelectronic device assembly 200.

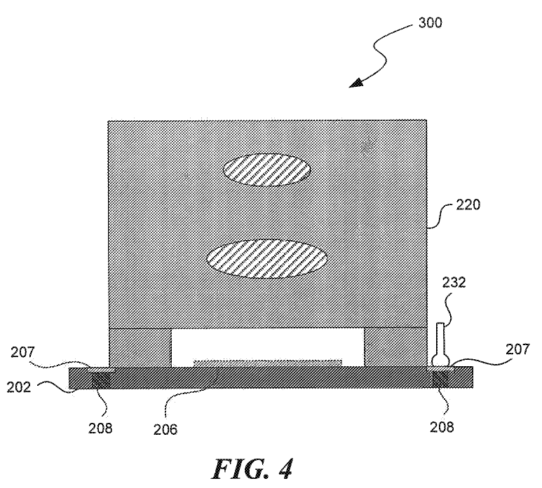

FIGS. 3-9 illustrate stages of an embodiment of a process for forming the imager assembly 200 of FIG. 2. FIG. 3 is a top view of a workpiece 300 during a stage of the process, and FIG. 4 is a cross-sectional view of one of the imager dies 202 in FIG. 3. As shown in FIG. 3, an early stage of the process includes forming a plurality of imager dies 202 on the workpiece 300. In the illustrated embodiment, forming the imager dies 102 includes forming 16 imager dies 202; however, in other embodiments, any desired number of imager dies 202 can be formed in the workpiece 300. Individual imager dies 202 can include a plurality of bond sites 207 and corresponding vias 208 (shown in phantom lines for clarity) proximate to the sensor array 206. The workpiece 300 can also include first gaps 302a and second gaps 302b (typically referred to as “a saw streets”) separating each pair of adjacent imager dies 202 from one another. The first gaps 302a have a first width and extend along a first direction. The second gaps 302b have a second width generally equal to the first width and extend along a second direction generally normal to the first direction. In other embodiments, the first and second gaps 302a-b can have other relative dimensions and/or relative orientations.

Referring to FIGS. 3 and 4 together, a subsequent stage of the process includes forming the shield interconnect 232 on the imager die 202. In the illustrated embodiment, forming the shield interconnect 232 includes forming a stud bump on a corresponding bond sites 207 using plating, printing, and/or other techniques to deposit a volume of gold, copper, and/or other conductive material. In other embodiments, forming the shield interconnect 232 can also include forming a pillar bump, a solder bump, and/or other conductive structure on the bond site 207. Even though FIG. 3 and FIG. 4 show the shield interconnect 232 as formed on a specific bond site 207 of all the imager dies 202, in other embodiments, the shield interconnects 232 can be formed on any of the bond sites 207. In further embodiments, individual shield interconnects 232 can be formed on different bond sites 207 for different imager dies 202.

As shown in FIG. 4, another stage of the process includes attaching the objective lens 220 to the imager die 202 formed in the workpiece 300. The objective lens 220 can be attached to the imager die 202, a fastener, and/or suitable fastening components.

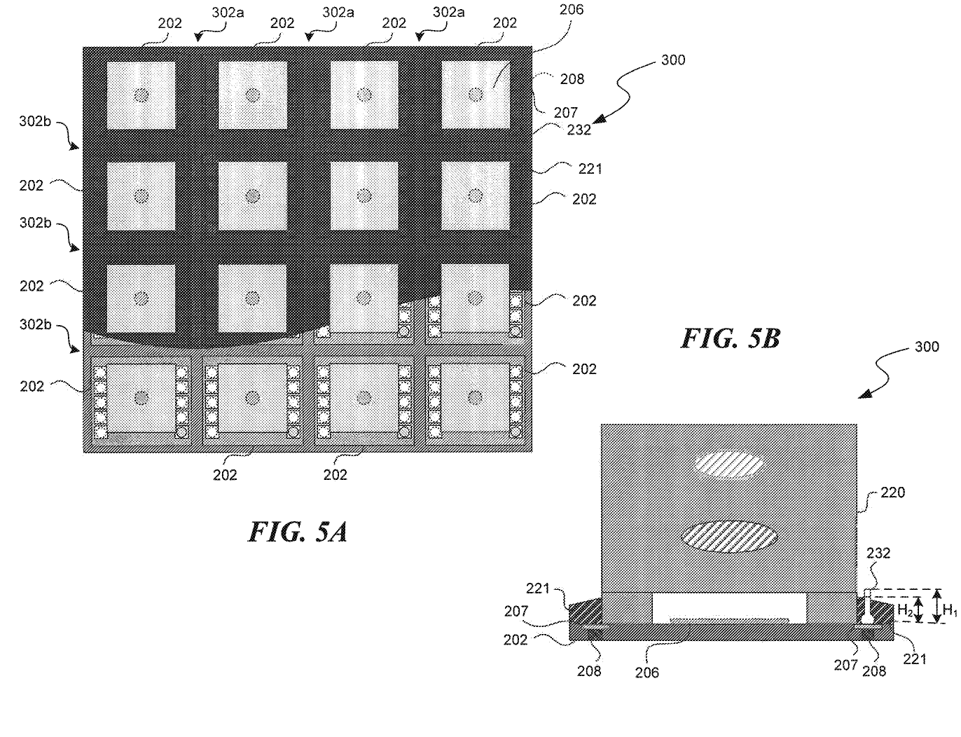

FIG. 5A is a partially exploded top view of the workpiece 300 during another processing stage, and FIG. 5B is a cross-sectional view of one of the imager dies 202 in FIG. 5A. This processing stage includes forming the first sidewall 221 on individual imager dies 202 formed in the workpiece 300. As shown in FIG. 5B, the shield interconnect 232 extends a first distance H₁ from the first surface 204a, and the first sidewall 221 extends a maximum second distance H₂ from the first surface 204a. In one embodiment, forming the first sidewall 221 includes dispensing a first liquid dielectric encapsulant (e.g., epoxy) onto the workpiece 300 and controlling the amount of the dispensed encapsulant such that the first distance H₁ is not shorter than the second distance H₂. In another embodiment, forming the first sidewall 221 includes disposing a sheet of dielectric material having apertures corresponding to the objective lenses 220 and the shield interconnects 232. In further embodiments, the first sidewall 221 can be formed using printing, spraying, and/or other suitable techniques. In other embodiments, the first sidewall 221 can also be formed using transfer molding, injection molding, compression molding, and/or other suitable molding techniques.

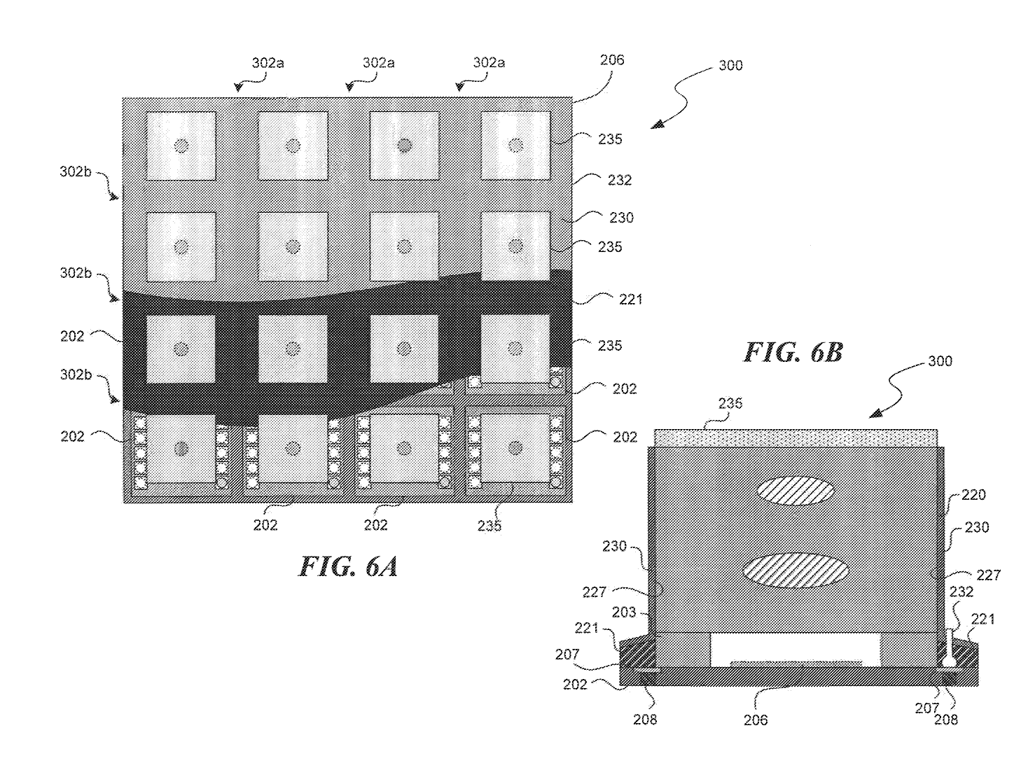

FIG. 6A is a partially exploded top view of the workpiece 300 during another processing stage that includes depositing a layer of conductive material onto the workpiece 300 to form the conductive shield 230. FIG. 6B is a cross-sectional view of one of the imager dies 202 in FIG. 6A after forming the conductive shield 230. Suitable techniques for depositing the layer of conductive material can include printing, spraying, sputtering, and/or other suitable techniques. During this processing stage, the process can optionally include attaching a protective tape 235 on top of the objective lens 220 prior to depositing the layer of conductive material. The protective tape 235 can avoid depositing the conductive material on top of the objective lens 220. After the deposition process, the protective tape 235 can be removed from the objective lens 220.

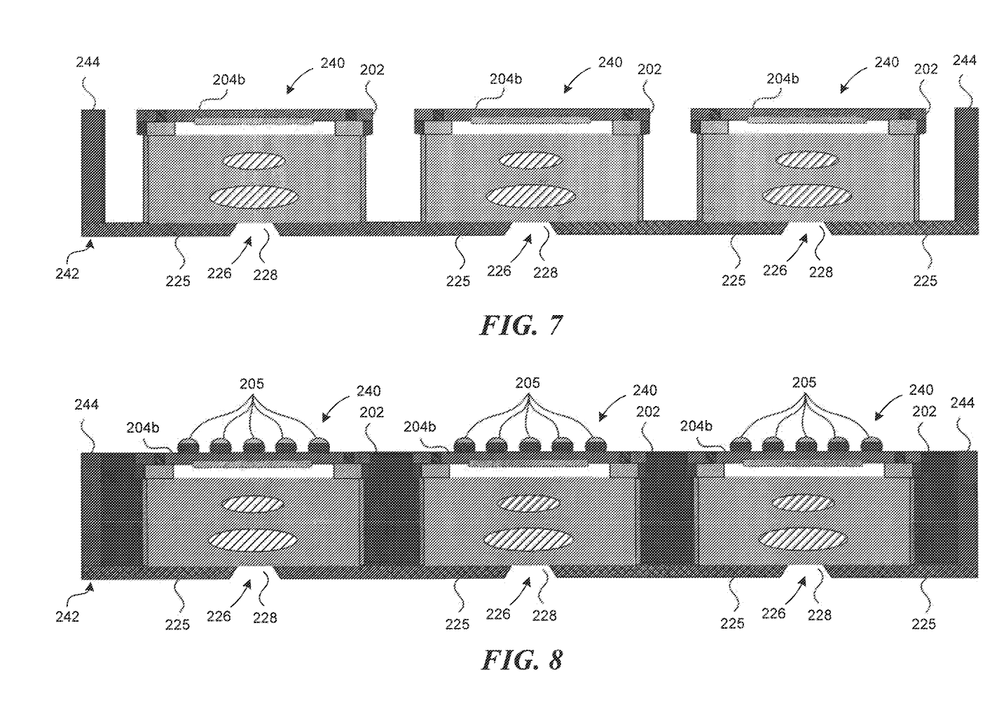

FIG. 7 illustrates another stage of the process that includes singulating the imager dies 202 with the attached objective lens 220 from the workpiece 300 (FIG. 6A) into individual imager subassemblies 240 and placing them onto a molding strip 242. The molding strip 242 includes a plurality of hoods 225 forming a base with openings 226 configured to receive a portion of the objective lenses 220. The molding strip 242 can also include dam portions 244 at least partially enclosing the base.

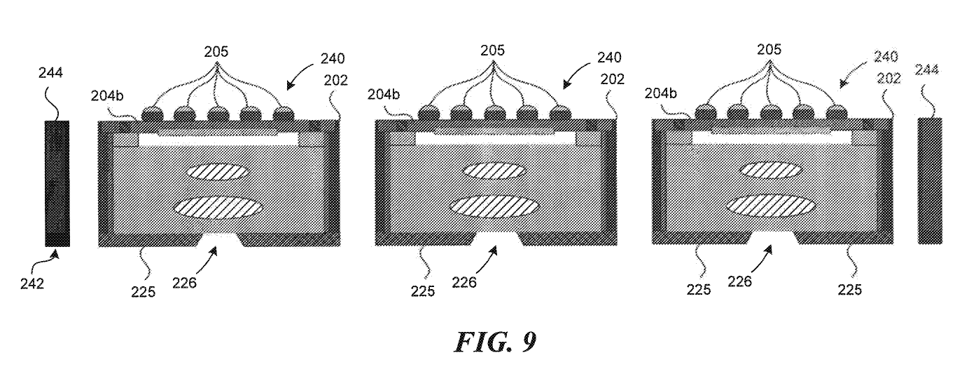

FIG. 8 illustrates another processing stage including dispensing a second liquid dielectric encapsulant into the molding strip 242 to encapsulate the imager subassemblies 240. The second liquid dielectric encapsulant can be the same as or different from the first liquid dielectric encapsulant. The process also includes attaching the plurality of solder balls 205 onto the second surface 204b of individual imager dies 202. In further embodiments, the imager subassemblies 240 can also be encapsulated with the second encapsulant using transfer molding, injection molding, compression molding, and/or other suitable molding techniques. FIG. 9 shows another stage of the process in which the imager subassemblies 240 are singulated to obtain the imager assembly 200 of FIG. 2.

The process described above with reference to FIGS. 3-9 can have additional and/or different process stages. For example, depositing the layer of conductive material onto the workpiece 300 can be performed after the singulating the imager dies 202 and placing the imager subassemblies 240 onto the molding strip 242.

FIG. 10 is a partially schematic cross-sectional view of an imager assembly 400 having a conductive shield 430 in accordance with another embodiment of the disclosure. As shown in FIG. 10, the imager assembly 400 can include a sidewall 421 and a hood 225 together at least partially encapsulating the objective lens 220 and the imager die 202. The sidewall 421 can include first sidewall surfaces 431a in direct contact with the lens side surfaces 227 of the objective lens 220 and second sidewall surfaces 431b opposite corresponding first sidewall surfaces 431a. In the illustrated embodiment, the second sidewall surfaces 431b are generally aligned with corresponding tape side surfaces 233 and extending beyond the edge 239 of the imager die 202. In other embodiments, the second sidewall surfaces 431b can be offset from the corresponding tape side surfaces 233, can be generally aligned with the edge 239 of the imager die 202, or can be extending inwardly from the edge 239.

The imager assembly 400 can also include a conductive shield 430 proximate to the dielectric sidewall 421. In the illustrated embodiment, the conductive shield 430 includes a layer of conductive material plated onto and substantially completely covering the second sidewall surfaces 431b. The conductive material can include copper, aluminum, nickel, gold, silver, platinum, and/or other suitable metal or metal alloys. In one embodiment, the conductive shield 430 can include a layer of copper with a thickness of about 1 micrometer to about 10 micrometers electroplated onto the second sidewall surfaces 431b. In other embodiments, the conductive shield 430 can include a layer of conductive material with any desired thicknesses. In further embodiments, portions of the conductive shield 430 may have different thicknesses.

The imager assembly 400 can further include a shield interconnect 432 that electrically connects the conductive shield 430 to at least one of the solder balls 205 via a corresponding bond site 207 and via 208. The shield interconnect 432 can be in direct contact with one of the bond sites 207 and extend outwardly through the sidewall 421 to be in direct contact with the conductive shield 430. In the illustrated embodiment, the shield interconnect 432 includes a portion of a wirebond extending from the bond site 207 at least partially outwardly away from the objective lens 220 and the imager die 202. The shield interconnect 432 includes a first end 433 in direct contact with the bond site 207 and a second end 435 opposite the first end 433. The second end 435 is generally flush with the second sidewall surface 431b and in direct contact with the conductive shield 430. In other embodiments, the shield interconnect 432 can include other suitable conductive structures.

FIGS. 11-16 illustrate stages of an embodiment of a process for forming the imager assembly 400 of FIG. 10. The process can include forming a plurality of imager dies 202 on the workpiece 300 as described above with reference to FIG. 3 and singulating the workpiece 300 to obtain individual imager dies 202.

FIG. 11 is a top view of the imager dies 202 on a carrier 401 during a subsequent stage of the process. As shown in FIG. 11, the process can include arranging and placing the singulated imager dies 202 onto the carrier 401. The carrier 401 can include a substrate constructed from silicon, glass, metal, and/or other suitable material with sufficient rigidness. In the illustrated embodiment, first gaps 402a and second gaps 402b on the carrier 401 separate adjacent imager dies 202 from one another. The first gaps 402a have a first width and extend along a first direction. The second gaps 402b have a second width generally equal to the first width and extend along a second direction generally normal to the first direction. In other embodiments, the first and second gaps 402a-b can have other relative dimensions and/or relative orientations.

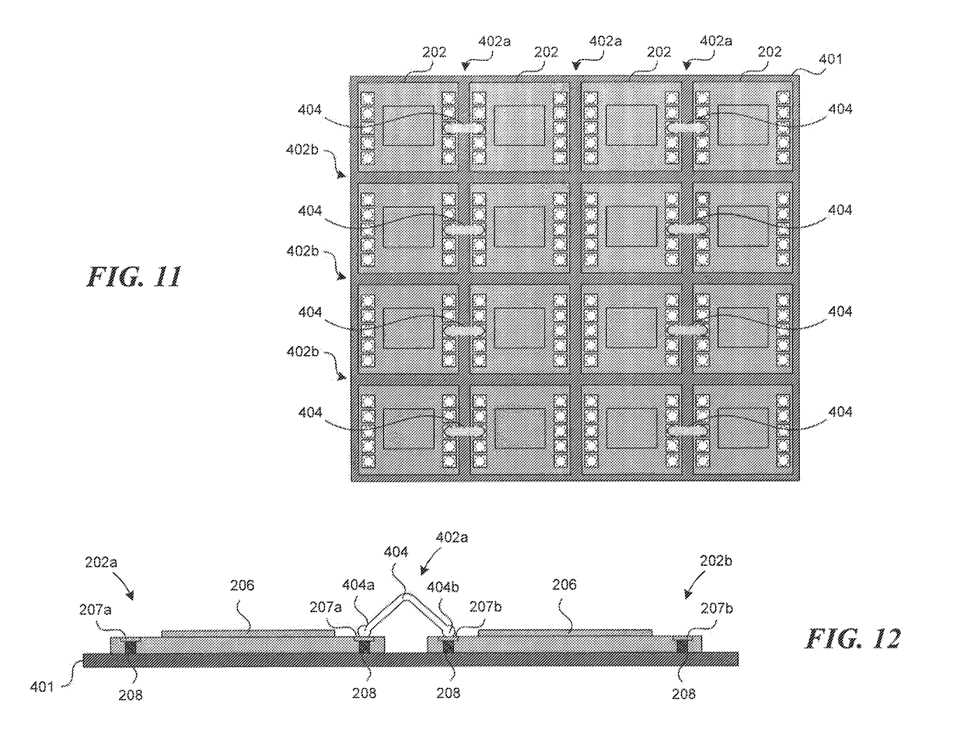

FIG. 12 is a cross-sectional view of two adjacent imager dies 202 (identified individually as a first imager die 202a and a second imager die 202b) on the carrier 401. Referring to FIGS. 11 and 12 together, another stage of the process includes electrically connecting corresponding bond sites of adjacent imager dies 202. In certain embodiments, wirebonding can be used to connect any one of the bond sites 207 on a particular imager die 202 to a corresponding bond site 207 on the adjacent imager die 202. As shown in FIG. 11, wirebonds 404 extends across the first gaps 402a. As shown in FIG. 12, one of the wirebonds 404 is in direct contact with a first bond site 207a on a first imager die 202a at a first end 404a. The wirebond 404 is also in direct contact with a second bond site 207b at a second end 404b. In other embodiments, the wirebonds 404 can be across the second gaps 402b or a combination of the first gaps 402a and the second gaps 402b. In further embodiments, more than one wirebonds 404 can connect a particular imager die 202 with one of more adjacent imager dies 202.

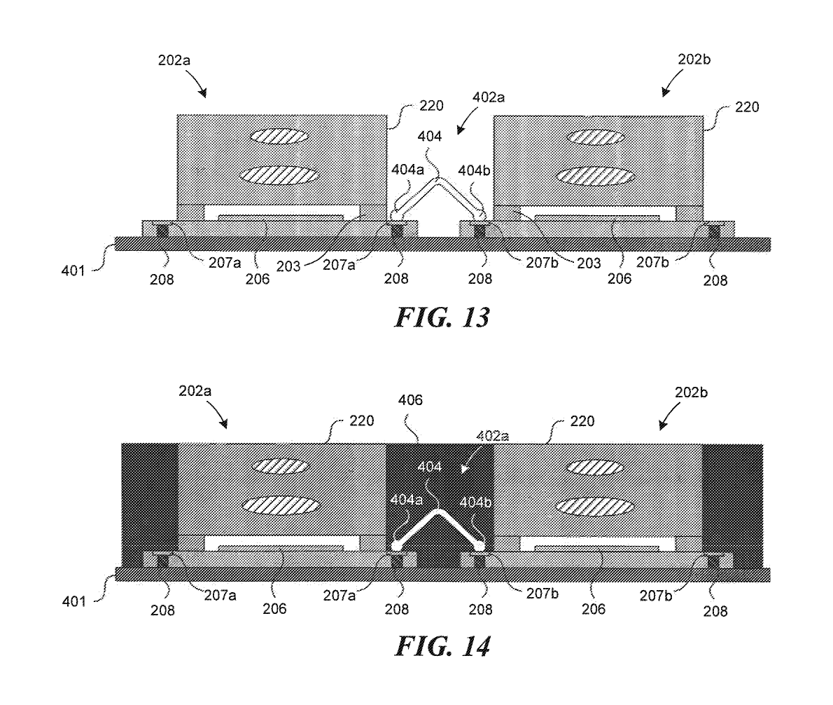

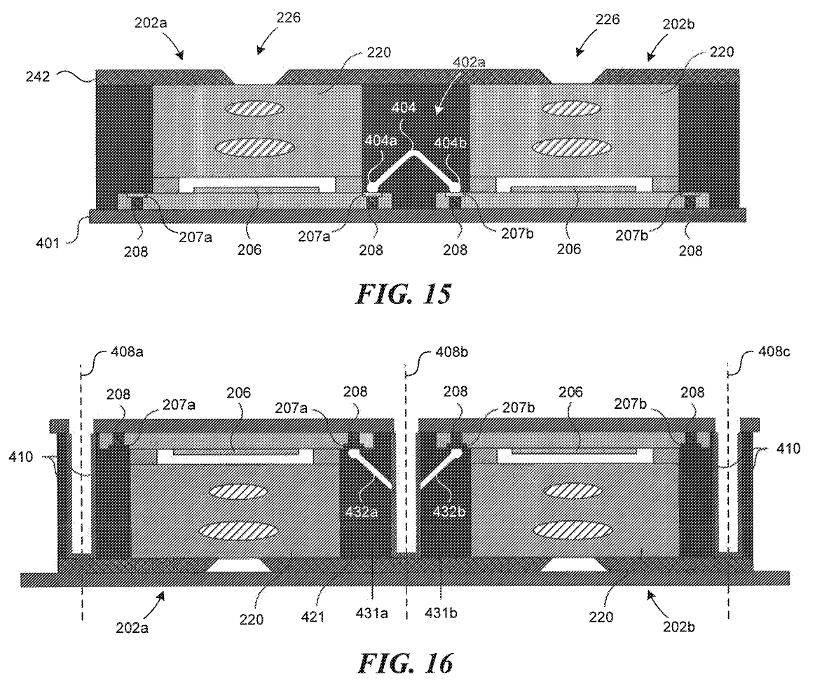

FIGS. 13-16 are cross-sectional views of the two adjacent imager dies 202a-b on the carrier 401 during subsequent stages of the process. FIG. 13 illustrates another stage of the process that includes attaching the objective lenses 220 to individual imager dies 202a-b. After the objective lenses 220 are attached, FIG. 14 illustrates another stage of the process that includes dispensing a liquid dielectric encapsulant 406 onto the carrier 401. The dispensed dielectric encapsulant 406 encapsulates the imager dies 202a-b and the objective lenses 220. In further embodiments, the imager dies 202a-b and the objective lenses 220 can also be encapsulated with the encapsulant 406 using transfer molding, injection molding, compression molding, and/or other suitable molding techniques. FIG. 15 illustrates another stage of the process, which includes placing the molding strip 242 onto the objective lenses 220. The openings 226 of the molding strip 242 individually correspond to and receive each of the objective lenses 220. As illustrated in FIG. 16, the encapsulated imager dies 202a-b and objective lenses 220 are partially singulated along lines 408a-c. As a result, the wirebond 404 is severed into a first shield interconnect 432a and a second shield interconnect 432b.

As shown in FIG. 16, the process further includes depositing a layer of conductive material 410 onto the partially singulated imager dies 202a-b and the objective lenses 220 to form the conductive shield 430. Suitable techniques for depositing the layer of conductive material 410 can include printing, spraying, sputtering, and/or other suitable techniques. The process further includes completely singulating the encapsulated imager dies 202a-b and objective lenses 220 along lines 408a-c to obtain the imager assembly 400 of FIG. 10.

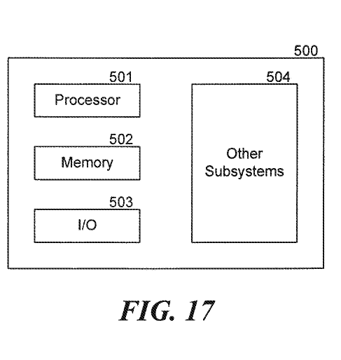

Embodiments of the imager assemblies 200 and 400 may be incorporated into any of myriad larger and/or more complex systems 500, a representative one of which is shown schematically in FIG. 17. The system 500 can include a processor 501, a memory 502, input/output devices 503, and/or other subsystems or components 504. Microfeature workpieces (e.g., in the form of microfeature dies and/or combinations of microfeature dies) may be included in any of the components shown in FIG. 17. The resulting system 500 can perform any of a wide variety of computing, processing, storage, sensor, and/or other functions. Accordingly, representative system 500 can include, without limitation, computers and/or other data processors, for example, desktop computers, laptop computers, Internet appliances, and hand-held devices (e.g., palm-top computers, wearable computers, cellular or mobile phones, multi-processor systems, processor-based or programmable consumer electronics, network computers, and mini computers). Another representative system 500 can include cameras, light sensors, servers and associated server subsystems, display devices, and/or memory devices. Components of the system 500 may be housed in a single unit or distributed over multiple, interconnected units, e.g., through a communications network. Components can accordingly include local and/or remote memory storage devices and any of a wide variety of computer-readable media, including magnetic or optically readable or removable computer disks.

From the foregoing, it will be appreciated that specific embodiments of the disclosure have been described herein for purposes of illustration, but that various modifications may be made without deviating from the disclosure. For example, many of the elements of one embodiment may be combined with other embodiments in addition to or in lieu of the elements of the other embodiments. Accordingly, the disclosure is not limited except as by the appended claims.

I claim:

1. A microelectronic device assembly, comprising:
a semiconductor substrate having a bond site and a solder ball electrically connected to the bond site;
a dielectric sidewall at least partially encapsulating the semiconductor substrate; and
a conductive shield in direct contact with the sidewall and in electrical communication with the solder ball and the bond site.

2. The microelectronic device assembly of claim 1 wherein the conductive shield includes a layer of conductive material plated onto the sidewall.

3. The microelectronic device assembly of claim 1, further comprising an objective lens attached to the semiconductor substrate, wherein the conductive shield includes a layer of conductive material plated onto the dielectric sidewall and side surfaces of the objective lens.

4. The microelectronic device assembly of claim 3 wherein the conductive shield includes a first portion plated onto the objective lens and a second portion plated onto the sidewall, the first portion being transverse to the second portion.

5. The microelectronic device assembly of claim 3 wherein the sidewall is a first sidewall, and wherein the microelectronic device assembly further includes a second sidewall encapsulating the first sidewall, and wherein the conductive shield includes a layer of conductive material between the first and second sidewalls.

6. The microelectronic device assembly of claim 1, further comprising an objective lens attached to the semiconductor substrate, wherein the sidewall at least partially encapsulates the semiconductor substrate and the objective lens, and wherein the conductive shield includes a layer of conductive material plated onto side surfaces of the sidewall.

7. The microelectronic device assembly of claim 6 wherein the sidewall includes a first surface proximate to the objective lens and the semiconductor substrate and a second surface opposite the first surface, and wherein the layer of conductive material is plated onto the second surface.

8. A microelectronic device assembly, comprising:
a semiconductor substrate carrying a bond site proximate to a first surface, a solder ball attached to a second surface opposite the first surface, and a via electrically connecting the bond site to the solder ball;
a dielectric sidewall at least partially encapsulating the semiconductor substrate;
a layer of conductive material in direct contact with the dielectric sidewall; and
a conductive interconnect extending between the bond site and the layer of conductive material through the dielectric sidewall.

9. The microelectronic device assembly of claim 8 wherein the bond site is a first bond site, and wherein the semiconductor substrate includes a second bond site adjacent to the first bond site, and wherein the sidewall is interposed between the second bond site and the layer of conductive material.

10. The microelectronic device assembly of claim 8 wherein the conductive interconnect is a stud bump extending through the dielectric sidewall from the bond site and in direct contact with the layer of conductive material.

11. The microelectronic device assembly of claim 10 wherein the stud bump extends beyond the layer of conductive material.

12. The microelectronic device assembly of claim 8 wherein the sidewall is a first dielectric sidewall, and wherein the imager assembly further includes a second dielectric sidewall encapsulating the layer of conductive material, the conductive interconnect, the first dielectric sidewall, and the semiconductor substrate.

13. The microelectronic device assembly of claim 8 wherein the conductive interconnect includes a portion of a wirebond extending at least partially outwardly away from the objective lens and toward the layer of conductive material.

14. The microelectronic device assembly of claim 13 wherein the portion of the wirebond includes a first end carried by the bond site and a second end opposite the first end, the second end being in direct contact with the layer of conductive material.

15. The microelectronic device assembly of claim 13 wherein the wirebond includes a first end carried by the bond site and a second end opposite the first end, the second end being generally flush with a surface of the dielectric sidewall, and wherein the layer of conductive material is in direct contact with the surface of the sidewall and the second end of the wirebond.

16. The microelectronic device assembly of claim 13 wherein the wirebond includes a first end carried by the bond site and a second end opposite the first end, the second end being exposed from the sidewall and in direct contact with the layer of conductive material.

17. A process for forming a microelectronic device assembly, comprising:
forming a conductive interconnect on a bond site carried by a microelectronic device;
encapsulating the bond site and the conductive interconnect with a dielectric sidewall;
controlling an amount of the dielectric sidewall such that the conductive interconnect extends beyond the dielectric sidewall; and
depositing a layer of conductive material onto the conductive interconnect and the dielectric sidewall.

18. The process of claim 17 wherein forming a conductive interconnect includes forming a stud bump on the bond site.

19. The process of claim 17 wherein depositing a layer of conductive material includes directly contacting the conductive interconnect with the layer of conductive material.

20. The process of claim 17 wherein controlling an amount of the dielectric sidewall includes controlling an amount of the dielectric sidewall such that a height of the conductive interconnect is not less than a height of the dielectric sidewall.

21. The process of claim 17 wherein the dielectric sidewall is a first dielectric sidewall, and wherein the process further includes encapsulating the layer of conductive material, the conductive interconnect, the first dielectric sidewall, and the microelectronic device with a second dielectric sidewall.

22. A process for forming a microelectronic device assembly, comprising:
forming a first microelectronic device adjacent to a second microelectronic device on a workpiece, the first microelectronic device having a first bond site and the second microelectronic device having a second bond site;
forming a conductive link between the first bond site and the second bond site;
encapsulating the first and second microelectronic devices and the conductive link with a dielectric sidewall;
severing the conductive link into a first conductive interconnect and a second conductive interconnect; and
depositing a layer of conductive material onto the dielectric sidewall such that the layer of conductive material is in direct contact with the first and second conductive interconnects.

23. The process of claim 22 wherein forming a conductive link includes disposing a wirebond between the first and second bond sites.

24. The process of claim 22 wherein severing the conductive link includes partially singulating the workpiece and removing a portion of the dielectric sidewall.

25. The process of claim 22 wherein depositing a layer of conductive material includes coating the dielectric sidewall with a layer of copper, aluminum, or nickel with a thickness of about 1 micrometer to about 10 micrometers.
